(19) United States
(12) Patent Application Publication
(10) Pub. No.: US 2012/0286351 A1
(43) Pub. Date: Nov. 15, 2012

(54) CELL ARRAY

(75) Inventor: Seung Wan KIM, Icheon (KR)

(73) Assignee: Hynix Semiconductor Inc., Icheon (KR)

(21) Appl. No.: 13/187,167

(22) Filed: Jul. 20, 2011

(30) Foreign Application Priority Data
May 12, 2011 (KR) 10-2011-0044737

(51) Int. Cl. H01L 29/78

(52) U.S. Cl. 257/329; 257/E29.262

(57) ABSTRACT

A semiconductor device includes a plurality of pillars disposed to protrude from a semiconductor substrate, bit lines surrounding perimeters of portions of the plurality of pillars and extending in a first direction, gates spaced apart from the bit lines, surrounding perimeters of portions of the plurality of pillars over the bit lines, and extending to a second direction perpendicular to the first direction, and separation layers separating the gates parallel to the second direction. Therefore, the semiconductor device suitable to the high integration of semiconductor devices can be implemented.

### CROSS-REFERENCES TO RELATED APPLICATION

The present application claims priority to Korean patent application number 10-2011-0044737 filed on 12 May 2011, which is incorporated by reference in its entirety.

### BACKGROUND OF THE INVENTION

1. Technical Field

The present invention relates to a unit cell, a cell array, a semiconductor device, a semiconductor module, a semiconductor system, an electronic unit, an electronic system and a method for forming the same, and more particularly, a unit cell having a vertical cell structure, a cell array, a semiconductor device, a semiconductor module, a semiconductor system, an electronic unit, an electronic system and a method for forming the same.

2. Related Art

Most electronic appliances include semiconductor devices. Semiconductor devices include electric elements such as transistors, resistors, capacitors and the like. The electric elements are designed to perform partial functions of the electronic appliances and are integrated on a semiconductor substrate. For example, electronic appliances such as computers or digital cameras include memory chips for storing information and processing chips for controlling the information and the memory chips and processing chips include the electric elements integrated on the semiconductor substrate.

On the other hand, semiconductor devices need to be more highly integrated to satisfy user demands for good performance and low price. As integration degree of semiconductor devices increases, the design rule is scaled down and patterns of the semiconductor devices become fine. As semiconductor devices become extra miniaturized and more highly integrated, although total chip area increases in proportion to the increase in memory capacity, a cell area where patterns of semiconductor devices are formed is substantially reduced. Since as many patterns as possible have to be formed in the limited cell area to ensure the desired memory capacity, fine patterns having a reduced critical dimension (CD) have to be formed.

Thereby, a method of reducing a unit area of a cell storing 1 bit has been studied. Currently, studies on a method of reducing chip size of dynamic random access memory (DRAMs) devices and increasing the number of chips on a wafer by implementing a unit cell of 1K in 6F2 or 4F2 configurations rather than an 8F2 configuration have progressed. Among them, a study on 4F2 transistors capable of forming cells that are highly integrated when the same design rule is applied as compared with a present level has progressed.

In a 4F2 cell architecture, a source and a drain of a cell transistor—that is, the source of a capacitor formation region in which charges are stored and the drain from which charges are drained to a bit line—need to fit in a 1F2 configuration. Recently, a vertical cell transistor structure in which a source and a drain are formed in a 1F2 configuration has been studied. The vertical cell transistor has a structure such that a cylinder type active region is vertically formed on a wafer. Thus, an impurity region and a gate are simultaneously formed. That is, the structure of an 8F2 configuration, where a source region and a drain region are horizontally formed, is replaced with a structure that a source region and a drain region are vertically formed so that a unit cell can be formed in 4F2 area. In a conventional 4F2 structure, one transistor is included in a unit cell.

### SUMMARY

The present invention is to provide a semiconductor cell demanded with high integration.

According to one aspect of an exemplary embodiment, a cell array includes first and second pillars disposed to protrude from a semiconductor substrate; bit lines surrounding the first and second pillars and extending along a first direction; first and second gates spaced apart from the bit lines, formed over the bit lines, and extending along a second direction perpendicular to the first direction, the first gate surrounding a portion of the first pillar, the second gate surrounding a portion of the second pillar; and a separation layer separating the first and second gates along the second direction.

The semiconductor cell may further include first and second storage units formed over the first and second the pillars separated by the separation layer.

Each of the bit lines includes a first bit line conduction layer surrounding the first and second pillars and a second bit line conduction layer coupling the first bit line conduction layers along the first direction.

Each of the first and second gates includes a first gate conduction layer surrounding the first and second pillars and a second gate conduction layer coupling the first gate conduction layers along the second direction.

The first and second gate conduction layer is divided into two parts by the separation layer, each of the two parts having substantially the same width.

The cell array may further include a first junction region formed between the first and second pillars and the bit lines.

The cell array may further include a second junction region formed between the first and second pillars and the storage units.

The cell array may further include an ion implanted region configured to control a driving voltage at a sidewall of each of the first and second pillars over which the gate is disposed.

According to another aspect of an exemplary embodiment, a cell array includes a first pillar and a second pillar formed in a unit cell along a first direction; a first bit line pattern surrounding the first pillar at a first level, and a second bit line pattern surrounding the second pillar at a second level; a bit line coupling the first and the second bit line pattern to each other along the first direction; a first separation layer dividing the first pillar into a third pillar and a fourth pillar along a second direction perpendicular to the first direction; a second separation layer dividing the second pillar into a fifth pillar and a sixth pillar along the second direction perpendicular to the first direction; first, second, third and fourth gate patterns surrounding the third, the fourth, the fifth and the sixth pillars at third, fourth, fifth and sixth levels, respectively; a first gate line coupling the first gate pattern to that of a neighboring unit cell with each other along the second direction; and second, third and fourth gate lines coupling the second, the third and the fourth gate patterns to those of the neighboring unit cell with each other along the second direction, respectively.

The unit cell includes at least four pillar patterns, at least four gate patterns and at least two bit lines.

The first and the second levels are different from the third, the fourth, the fifth and the sixth levels.

The first and the second levels are at substantially the same level, and the third, the fourth, the fifth and the sixth levels are at substantially the same level.

The first, second, third and fourth gate patterns are configured to be insulated from the first and the second bit line patterns.

The first, second, third and fourth gate patterns are formed at a level higher than the first and the second bit line patterns, respectively.

The cell array further may comprise first and second storage node patterns configured to be coupled to the first bit line pattern through the third and the fourth gate patterns and third and fourth storage node patterns configured to be coupled to the second bit line pattern through the fifth and the sixth gate patterns.

According to another aspect of an exemplary embodiment, a method of forming a cell array includes forming a plurality of pillars protruding from a semiconductor substrate, forming bit lines surrounding perimeters of portions of the plurality of pillars and extending in a first direction, forming gates spaced apart from the bit lines, surrounding perimeters of portions of the plurality of the pillars over the bit lines and extending in a second direction perpendicular to the first direction, and forming separation layers separating the gates and parallel to the second direction.

The forming the bit lines may include forming first bit line conduction layers surrounding the plurality of pillars and second bit line conduction layers connecting the first bit line conduction layers in the first direction.

The forming each of the first bit line conduction layers may include forming the bit line conduction layers to be buried within the pillars and etching back the bit line conduction layers, forming first spacers at sidewalls of the bit line conduction layer and the pillars, etching the bit line conduction layer using the first spacers as a mask, and forming a bit line separation insulating layer to be buried within the first spacers.

The method may further include, after forming the bit line conduction layer, performing a heat treatment process to form a first junction region at a sidewall of each of the pillars.

The forming each of the second bit line conduction layers may include removing the first spacers disposed at sidewalls of adjacent pillars in the first direction, forming a bit line conduction layer buried between adjacent pillars in the first direction, and etching back the bit line conduction layer.

The method may further include, after forming the second bit line conduction layer, forming an insulating layer on the first bit line conduction layer and the second bit line conduction layer and performing an etch back process for the first spacers and the bit line separation insulating layer buried between pillars adjacent in the second direction and the insulating layer to form an interlayer insulating layer on the first bit line conduction layer, the second bit line conduction layer and the semiconductor substrate.

The method may further include, before the forming the gates, performing an ion implantation process on exposed sidewalls of the pillars over the interlayer insulating layer to adjust a threshold voltage.

The forming the gates may include forming gate conduction layers surrounding the pillars and forming second gate conduction layers connecting the first gate conduction layers in the second direction.

The forming each of the first gate conduction layers may include forming a conduction layer on the interlayer insulating layer and performing an etch back process, forming second spacers at sidewalls of the pillars and the interlayer insulating layer, and etching the conduction layer using the second spacers as a mask.

The forming each of the second gate conduction layers may include forming a gate separation insulating layer between the first gate conduction layers, forming a mask pattern between the pillars that are adjacent in the first direction and extending in the second direction, and etching the gate separation insulating layer to expose the interlayer insulating layer using the mask pattern as a mask, thereby forming a trench, and forming a conduction layer within the trench and performing an etch back process.

The forming the separation layers may include forming a trench to separate the gates and to be parallel in the second direction and burying the insulating layer in the trench.

The forming the trench may include separating the gates by the same width as the trench.

The method may further include, after forming the separation layers, performing an ion implantation process on upper portions of the pillars to form second junction regions.

The method may further include, after forming the second junction regions, forming storage units on the second junction regions.

According to another aspect of an exemplary embodiment, a semiconductor device includes a plurality of pillars disposed to protrude from a semiconductor substrate, bit lines surrounding perimeters of portions of the plurality of pillars and extending in a first direction, gates spaced apart from the bit lines, surrounding perimeters of portions of the plurality of pillars over the bit lines, and extending in a second direction perpendicular to the first direction, and separation layers separating the gates parallel to the second direction, a signal amplification connected to the bit lines, a word line driving unit connected to the gates, and a driving unit connected to the signal amplification unit and the word line driving unit.

The semiconductor device may further include a row decoder, a column decoder, and a semiconductor device controller.

According to another aspect of an exemplary embodiment, a semiconductor module includes a semiconductor device and an external input/output (I/O) line. The semiconductor device includes a plurality of pillars disposed to protrude from a semiconductor substrate, bit lines surrounding perimeters of portions of the plurality of pillars and extending in a first direction, gates spaced apart from the bit lines, surrounding perimeters of portions of the plurality of pillars over the bit lines, and extending in a second direction perpendicular to the first direction, and separation layers separating the gates parallel to the second direction, a signal amplification unit connected to the bit lines, a word line driving unit connected to the gates, and a driving unit connected to the signal amplification unit and the word line driving unit. The external I/O line is electrically connected to the semiconductor device.

The semiconductor device may include one or a plurality of semiconductor devices.

The semiconductor module may further include a semiconductor module data link and a semiconductor module command link electrically connected to the external I/O line.

According to another aspect of an exemplary embodiment, a semiconductor system includes a semiconductor module and a system controller. The semiconductor module includes a semiconductor device and an external input/output (I/O) line. The semiconductor device includes a plurality of pillars disposed to protrude from a semiconductor substrate, bit lines surrounding perimeters of portions of the plurality of pillars and extending in a first direction, gates spaced apart from the bit lines, surrounding perimeters of portions of the plurality of pillars over the bit lines, and extending in a second direction perpendicular to the first direction, and separation layers separating the gates parallel to the second direction, a signal amplification unit connected to the bit lines, a word line driving unit connected to the gates, and a driving unit connected to the signal amplification unit and the word line driving unit. The external I/O line is electrically connected to the semiconductor device and the system controller is electrically connected to the semiconductor module.

The semiconductor module may include one or a plurality of semiconductor modules.

The semiconductor system may further include a system command link and a system data link electrically connected to the system controller.

According to another aspect of an exemplary embodiment, an electronic unit includes a semiconductor system and a processor. The semiconductor system includes a semiconductor module and a system controller. The semiconductor module includes a semiconductor device and an external input/output (I/O) line. The semiconductor device includes a plurality of pillars disposed to protrude from a semiconductor substrate, bit lines surrounding perimeters of portions of the plurality of pillars and extending in a first direction, gates spaced apart from the bit lines, surrounding perimeters of portions of the plurality of pillars over the bit lines, and extending in a second direction perpendicular to the first direction, and separation layers separating the gates parallel to the second direction, a signal amplification unit connected to the bit lines, a word line driving unit connected to the gates, and a driving unit connected to the signal amplification unit and the word line driving unit. The external input/output (I/O) is electrically connected to the semiconductor device, the system controller is electrically connected to the semiconductor module, and the processor is electrically connected to the semiconductor system.

The processor may include a central processing unit (CPU) or a graphic processing unit (GPU).

The CPU may be part of a computer or a mobile device.

The GPU may be part of a graphic device.

According to another aspect of an exemplary embodiment, an electronic system includes an electronic unit and an interface. The semiconductor system includes a semiconductor module and a system controller. The semiconductor module includes a semiconductor device and an external input/output (I/O) line. The semiconductor device includes a plurality of pillars disposed to protrude from a semiconductor substrate, bit lines surrounding perimeters of portions of the plurality of pillars and extending in a first direction, gates spaced apart from the bit lines, surrounding perimeters of portions of the plurality of pillars over the bit lines, and extending in a second direction perpendicular to the first direction, and separation layers separating the gates parallel to the second direction, a signal amplification unit connected to the bit lines, a word line driving unit connected to the gates, and a driving unit connected to the signal amplification unit and the word line driving unit. The external input/output (I/O) is electrically connected to the semiconductor device, the system controller is electrically connected to the semiconductor module, the processor is electrically connected to the semiconductor system, and the interface is connected to the electronic unit.

The interface may include any of a monitor, a key board, a pointing device (mouse), universal serial bus (USB), a display, and a speaker.

These and other features, aspects, and embodiments are described below in the section entitled “DESCRIPTION OF EXEMPLARY EMBODIMENT.”

### BRIEF DESCRIPTION OF THE DRAWINGS

The above and other aspects, features, and other advantages of the subject matter of the present disclosure will be more clearly understood from the following detailed description taken in conjunction with the accompanying drawings, in which:

FIG. 1 is a perspective view illustrating a semiconductor cell according to an exemplary embodiment of the present invention;

FIG. 2 is a view illustrating a cell array according to an exemplary embodiment of the present invention, wherein (i) is a plan view, (ii) is a cross-sectional view taken along a line X-X′ of (i), and (iii) is a cross-sectional view taken along a line Y-Y′ of (i);

FIG. 3 is a view illustrating a semiconductor chip according to an exemplary embodiment of the present invention;

FIG. 4 is a view illustrating an electronic unit according to an exemplary embodiment of the present invention;

FIG. 5 is a view illustrating a semiconductor module according to an exemplary embodiment of the present invention;

FIG. 6 is a view illustrating a semiconductor system according to an exemplary embodiment of the present invention;

FIG. 7 is a view illustrating an electronic system according to an exemplary embodiment of the present invention;

FIGS. 8A to 8N are views illustrating a method of forming a semiconductor cell according to an exemplary embodiment of the present invention, wherein (i) is a plan view, (ii) is a cross-sectional view taken along a line X-X′ of (i), and (iii) is a cross-sectional view taken along a line Y-Y′ of (i);

FIGS. 9 to 13 are perspective views illustrating a cell array according to an exemplary embodiment of the present invention.

### DESCRIPTION OF EXEMPLARY EMBODIMENT

Exemplary embodiments are described herein with reference to cross-sectional illustrations that are schematic illustrations of exemplary embodiments (and intermediate structures). As such, variations in the shapes of the illustrations as a result, for example, of manufacturing techniques and/or tolerances, are to be expected. Thus, exemplary embodiments should not be construed as limited to the particular shapes of regions illustrated herein, but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other layer or substrate, or intervening layers may also be present.

Hereinafter, a semiconductor device and a method of manufacturing the same according to an exemplary embodiment of the present invention will be described in detail with reference to accompanying drawings.

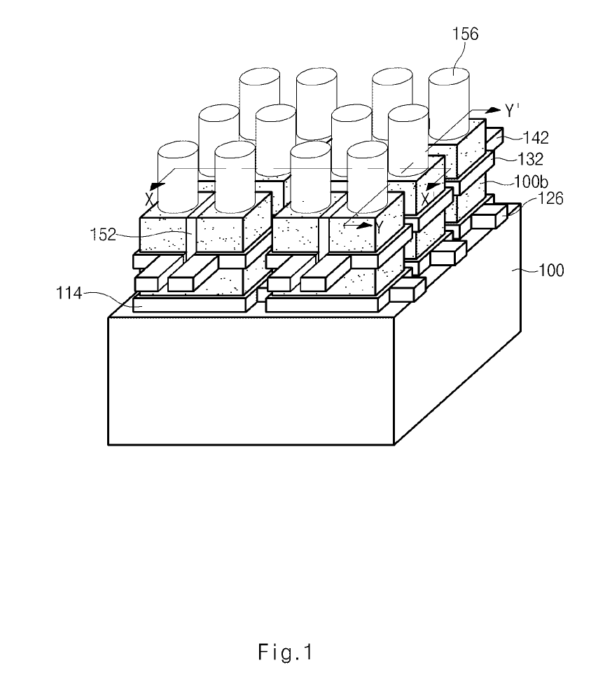

Referring to FIG. 1, the cell array may include a plurality of pillars 100b protruding from a semiconductor substrate 100, first bit line conduction layers 114 surrounding the perimeter of portions of the pillars 100b, second bit line conduction layers 126 connecting the first bit line conduction layers 114 and extending in a first direction (X-X′ direction), first gate conduction layers 132 surrounding the perimeter of portions of the pillars 100b, disposed over the first bit line conduction layers 114, and spaced apart from the first bit line conduction layers 114, second gate conduction layers 142 connecting the first gate conduction layers 132 and extending in a second direction (Y-Y′ direction) perpendicular to the first direction, and separation layer 152 separating the first gate conduction layers 132 and second gate conduction layers 142. The pillars 100b may be cylindrical or angular structure according on implementation. Accordingly, the term “perimeter” as used herein means a path that surrounds an area regardless of the shape of that area, i.e., the area surrounded by the “perimeter,” as used herein, can be circular, a closed curve, rectangular, square, or the like.

In an embodiment, the first gate conduction layers 132 and second gate conduction layers 142 separated by the separation layer 152 may be disposed parallel to each other in the second direction (y-y′ direction). The cell array may further include storage units 156 coupled to upper portions of the pillars 100b. The storage unit may include a capacitor.

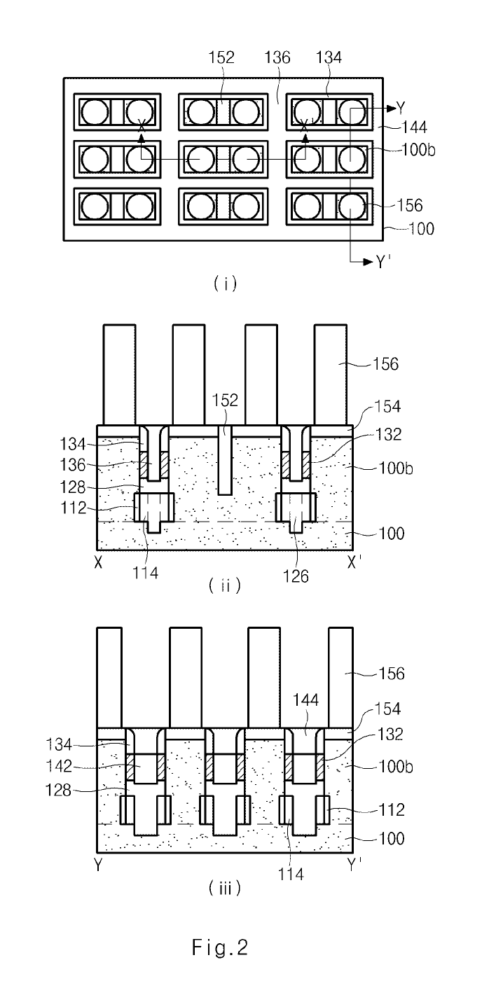

Hereinafter, the cell array will be described in more detail with reference to FIG. 2. FIG. 2 is a view illustrating a cell array according to an exemplary embodiment of the present invention, wherein (i) is a plan view, (ii) is a cross-sectional view taken along a line X-X′ of (i), and (iii) is a cross-sectional view taken along a line Y-Y′ of (i).

Referring to FIG. 2(i), the cell array includes the first gate conduction layers 132 and second gate conduction layers 142 separated by the separation layer 152 to be parallel in the second (Y-Y′) direction with the same width, the storage units 156 disposed over the pillars 100b separated by the separation layer 152, and a gate separation insulating layer 136 insulating the pillars 100b disposed adjacent to each other in the first (X-X′) direction. The cell array includes a second spacer 134 surrounding perimeters of the pillars 100b.

Referring to FIG. 2(ii), the cell array includes first junction regions 112 disposed in the pillars 100b and diffused into sidewalls of the pillars 100b by the first bit line conduction layers 114 and the second bit line conduction layers 126 disposed between the first bit line conduction layers 114. Further, the cell array includes an interlayer insulating layer 128 disposed over the first bit line conduction layer 114 and the second bit line conduction layer 126, the gate separation insulating layer 136 disposed between the first gate conduction layers 132 and between the second spacer 134 to insulate the first gate conduction layers 132 and the second spacer 134, which is disposed over the first gate conduction layer 132. The cell array includes a second junction region 154 disposed in an upper portion of each of the pillars 100b and the storage units 156 disposed over each of the pillars 100b and separated by the separation layer 152 in the first (X-X′) direction. In an embodiment, the separation layer 152 separating the first gate conduction layer 132 is preferably formed to a depth such that it is disposed between the pillars 100b to separate the first gate conduction layer 132 in the same width. In an embodiment, although not shown, a gate insulating layer may also be included between the first gate conduction layer 132 and the pillar 100b. Although not shown, contact plugs disposed between the storage unit 156 and the second junction region 154 may further be included.

Referring to FIG. 2(iii), the cell array includes the first junction region 112 diffused into a sidewall of the pillar 100b by the first bit line conduction layer 114 surrounding the pillar 100b, the interlayer insulating layer 128 configured to electrically insulate between adjacent first bit line conduction layers 114 and between the first bit line conduction layer 114 and the first gate conduction layer 132. The cell array further includes the first gate conduction layer 132 spaced apart from the first bit line conduction layer 114 by the interlayer insulating layer 128 and surrounding the pillar 100b, the second gate conduction layer 142 connecting the first gate conduction layers 132 in the second (X-X′) direction, the second spacer 134 disposed over the first gate conduction layer 132, an interlayer insulating layer 144 disposed over the second gate conduction layer 142, the second junction region 154 disposed in an upper portion of the pillar 100b and the storage unit 156 disposed over the second junction region 154.

Although not shown, a storage node contact plug disposed between the storage unit 156 and the second junction region 154 is further included. In an embodiment, the first bit line conduction layer 114 and the second bit line conduction layer 126 are coupled to serve as a bit line. The first gate conduction layer 132 and the second gate conduction layer 142 are coupled to serve as a gate.

As described above, according to an exemplary embodiment, the storage unit includes two pillars separated by a separation layer to provide a structure that is effective in a highly integrated semiconductor device. In addition, the bit line is connected to surround the perimeter of the pillar, thereby reducing resistance of the bit line.

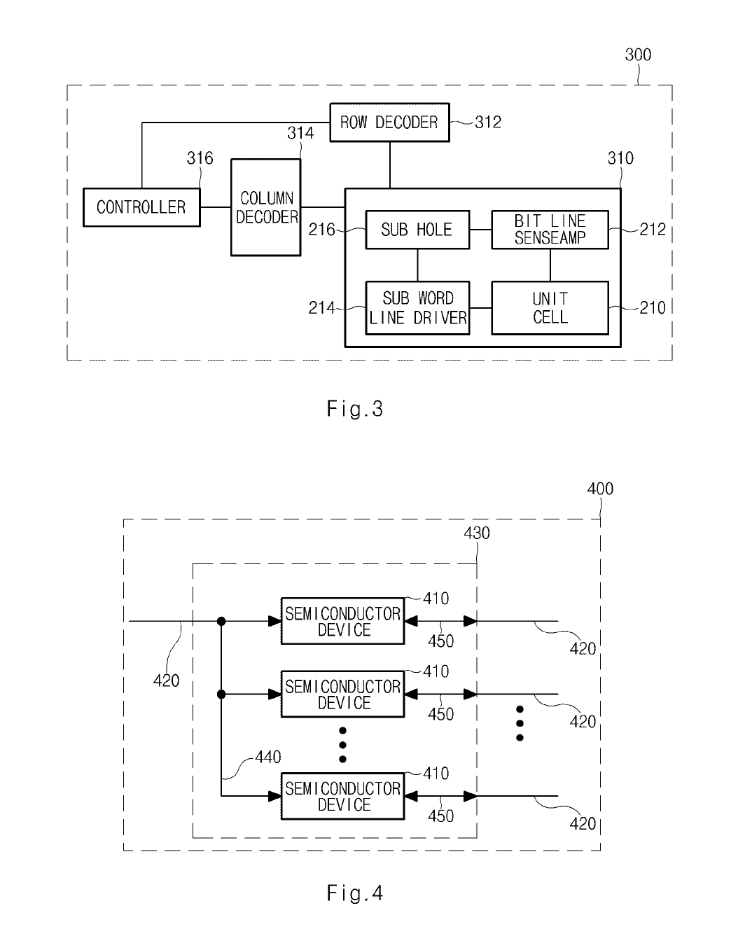

As shown in FIG. 3, the semiconductor device 300 includes a cell array 210, a signal amplification unit 212 which is a bit line sense amplifier 212 electrically coupled to bit lines disposed in the cell array 310, a word line driver 214 which is a sub word line driver coupled to gates and a sub hole 216 which is a driving unit. The semiconductor device 300 further includes a row decoder 312, a column decoder 314, and a semiconductor device controller 316. In an embodiment, the row decoder 312 may be a decoder for a row select signal coupled to the bit line and the column decoder may be a decoder for a column select signal coupled to the gate.

The semiconductor device according to an exemplary embodiment may be applied to dynamic random access memories (DRAMs), but it is not limited thereto. For example, it may also be applied to static random access memories (SRAMs), flash memories, ferroelectric random access memories (FeRAMs), magnetic random access memories (MRAMs), phase change random access memories (PRAMs), etc.

The above-described semiconductor device may be included in various electronic appliances, including, for example, desktop computers, portable computers, computing memories used in servers, graphics memories having various specs, and mobile memories, which have been the focus of a lot of attention in recent years with the advancement of mobile communication. Further, the above-described semiconductor device may be provided in various digital applications such as mobile recording mediums including, for example, memory sticks, multimedia cards (MMCs), secure digitals (SDs), compact flashes (CFs), extreme digitals (xDs) picture cards, universal serial buses (USBs), and flash devices as well as various applications such as MP3Ps, portable multimedia players (PMPs), digital cameras, camcorders, mobile phones, etc. A single type semiconductor device may be applied to a technology such as multi-chip package (MCP), disk on chip (DOC), or embedded device. The single type semiconductor device may be applied to a CMOS image sensor, which may be provided in various devices such as camera phones, web cameras, small-size image pick-up devices for medicine, etc.

Referring to FIG. 4, a semiconductor module 400 according to an exemplary embodiment includes one or a plurality of semiconductor devices 410 and an external input/output line 420. In an embodiment, the semiconductor device 410 has the same configuration as the semiconductor device 300 of FIG. 3 and the one or a plurality of semiconductor devices may be coupled to a support 430. The semiconductor module 400 may further include a semiconductor module command link 440 and a semiconductor module data link 450, which connect the external I/O line 420 and the semiconductor devices 410.

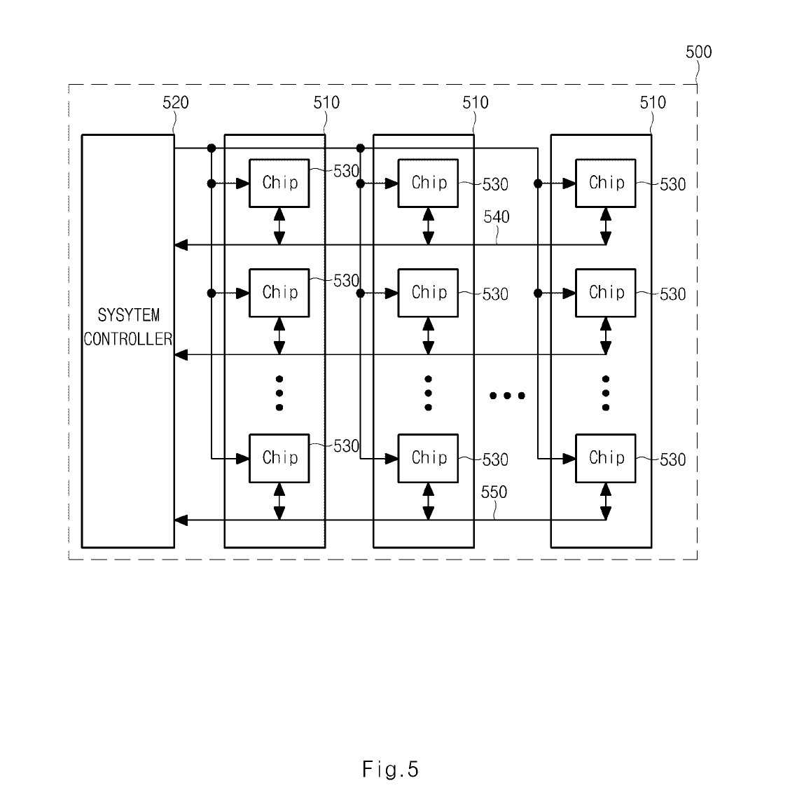

Referring to FIG. 5, a semiconductor system 500 according to an exemplary embodiment includes one or a plurality of semiconductor modules 510 and a system controller 520. In an embodiment, the semiconductor module 510 has the same configuration as the semiconductor module 400 of FIG. 4, and thus, each of the semiconductor modules 510 includes one or a plurality of semiconductor devices 530. The semiconductor device 530 has the same configuration as the semiconductor device 400 of FIG. 4 and as the semiconductor device 300 of FIG. 3. The semiconductor system 500 further includes a system command link 540 and a system data link 550 which electrically connect the semiconductor module 510 and the controller 520.

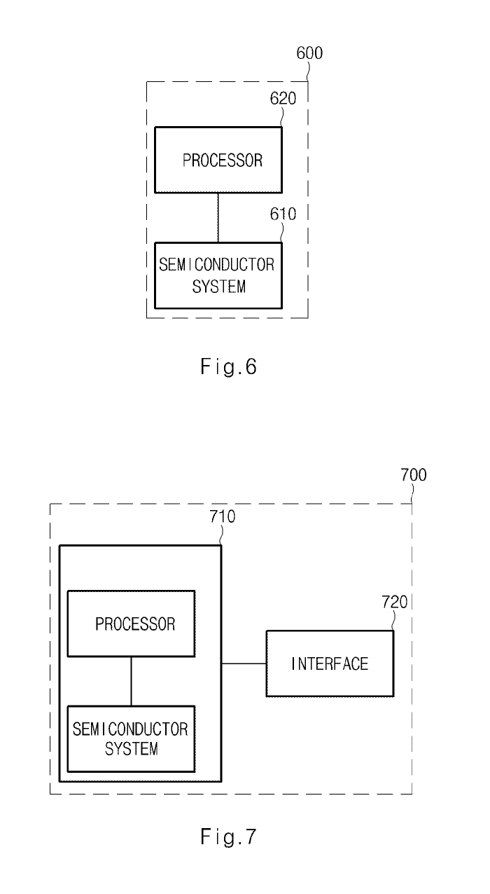

Referring to FIG. 6, an electronic unit 600 according to an exemplary embodiment includes a semiconductor system 610 and a processor 620 coupled to the semiconductor system 610. At this time, the semiconductor system 610 has the same configuration as the semiconductor system 500. In an embodiment, the processor 620 includes a central processing unit (CPU), a micro processor unit (MPU), a micro controller unit (MCU), a graphics processing unit (GPU) or a digital signal processor (DSP). In an embodiment, the CPU or MPU has a combined configuration of arithmetic logic unit (ALU), which is an arithmetic and logical operation unit, and a control unit, which reads and interprets commands to control each unit. When the processor is a CPU or MPU, the electronic unit may include computer appliances or mobile appliances. Further, a GPU is a CPU for graphic which is used to calculate numbers having a decimal point. The GPU is a processor which draws graphics on a screen in real time. When the processor is a GPU, the electronic unit may include graphic appliances. A DSP is a processor that quickly converts an analog signal (for example, audio) into a digital signal, calculates the converted signal and uses the calculated result or converts the calculated result into an analog signal again and uses the converted signal. The DSP typically calculates the digital value. When the processor is DSP, the electronic unit may include audio and video appliances.

In addition, the processor includes an accelerate processor unit (APU). The processor has a combined construction of a CPU with a GPU and a processor serving as a graphic card.

Referring to FIG. 7, an electronic system 700 includes an electric unit 710 and one or a plurality of interfaces 720 electrically connected to the electronic unit 710. In an embodiment, the electronic unit 710 has the same configuration as the electronic unit 600 of FIG. 6. The interface 720 may include a monitor, a key board, a pointing device (mouse), USB, a display, or a speaker, but it is not limited thereto and it may be changeable.

A method of manufacturing a semiconductor device having the above-described configuration according to an exemplary embodiment of the present invention will be described.

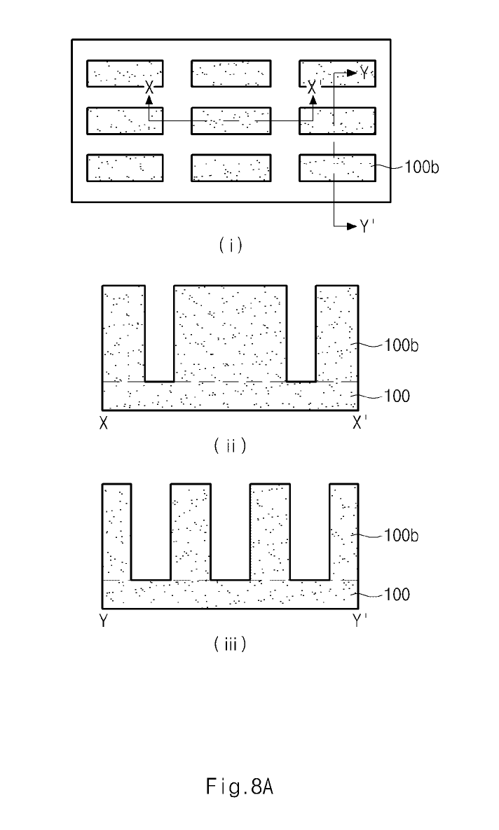

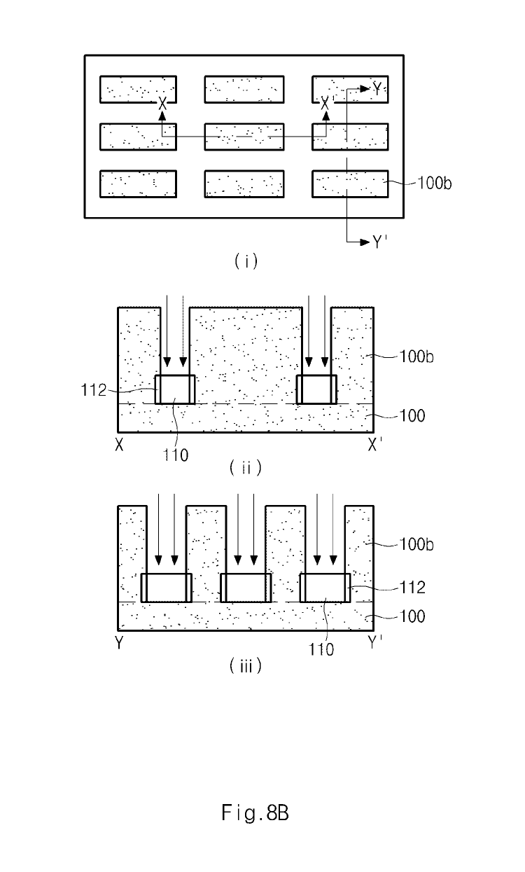

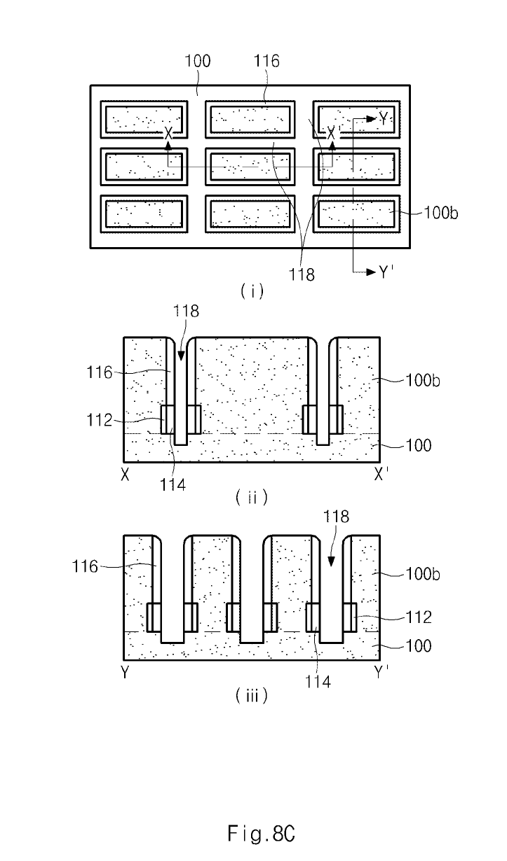

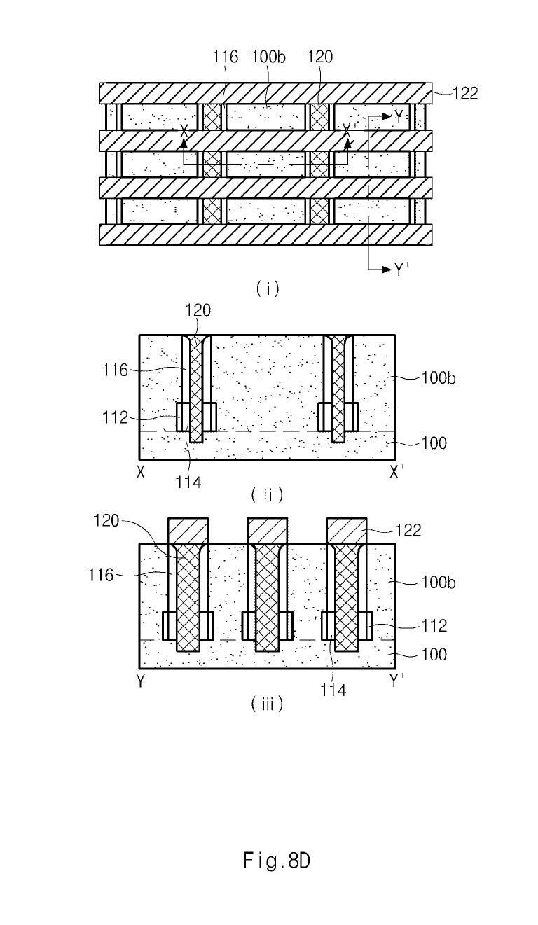

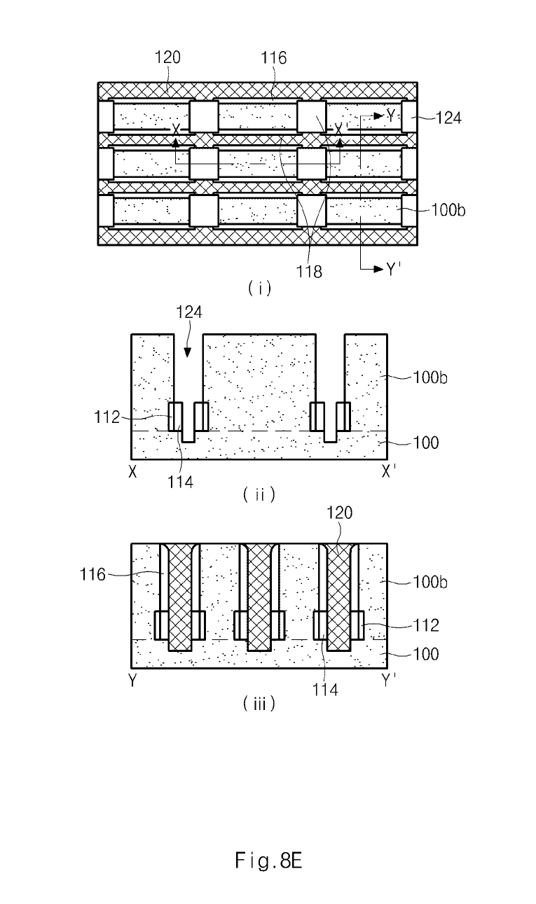

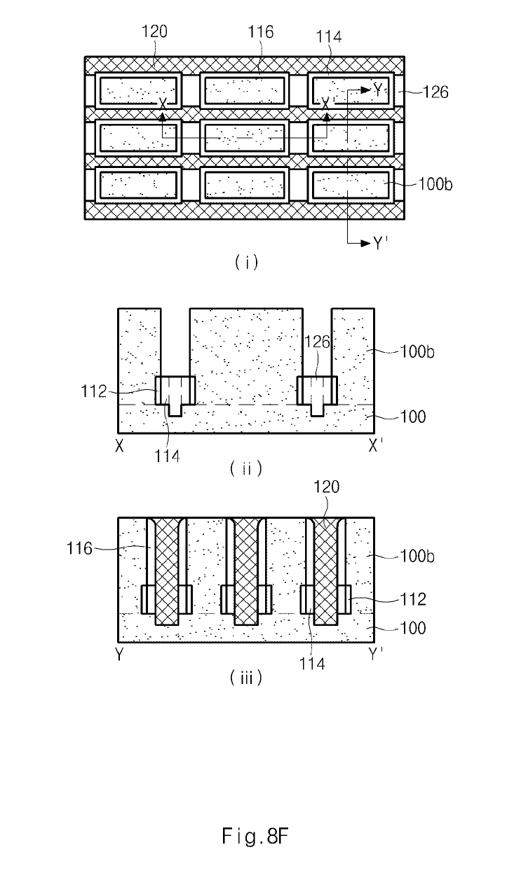

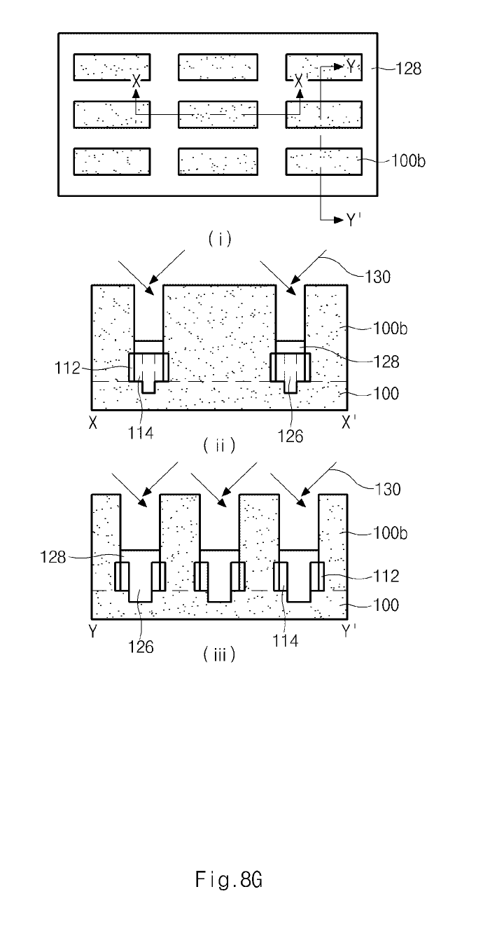

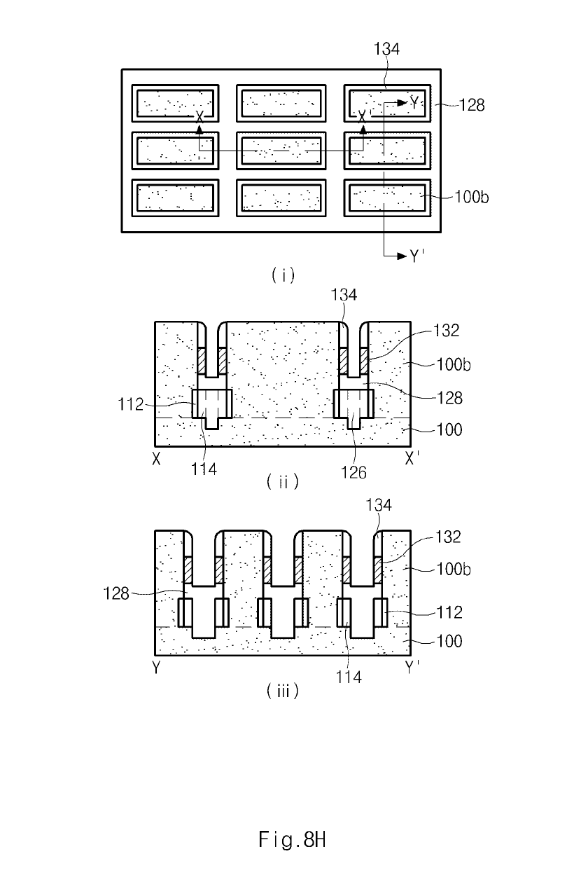

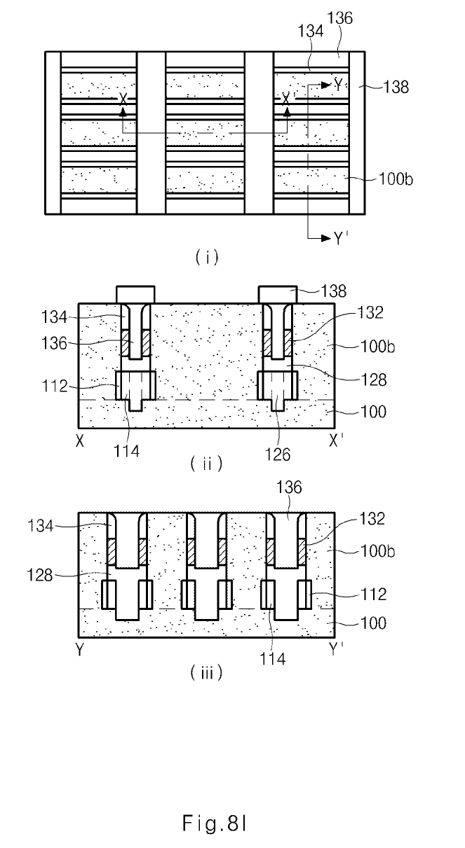

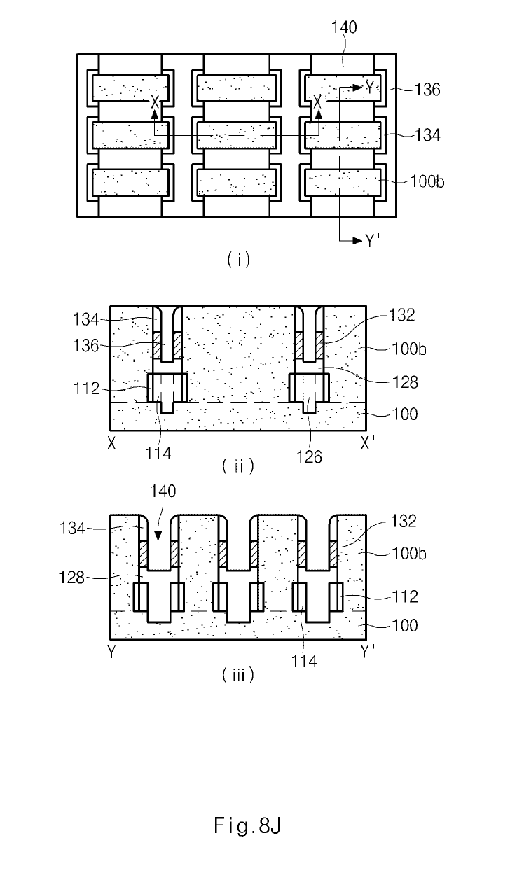

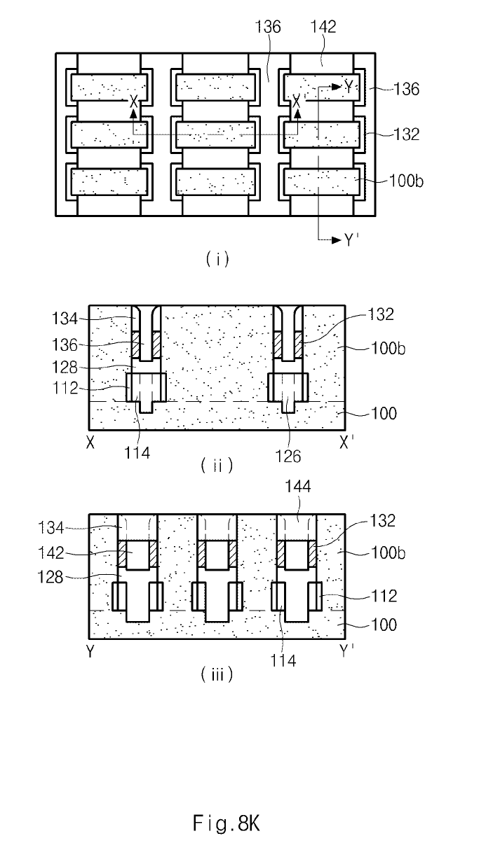

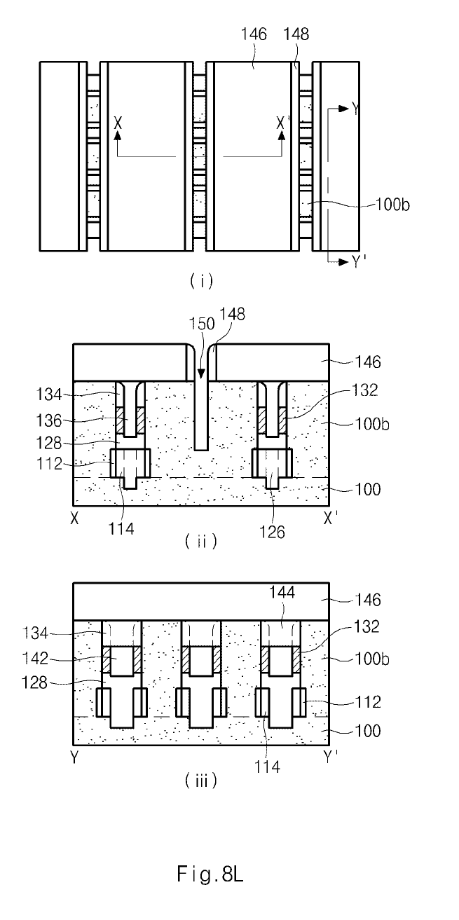

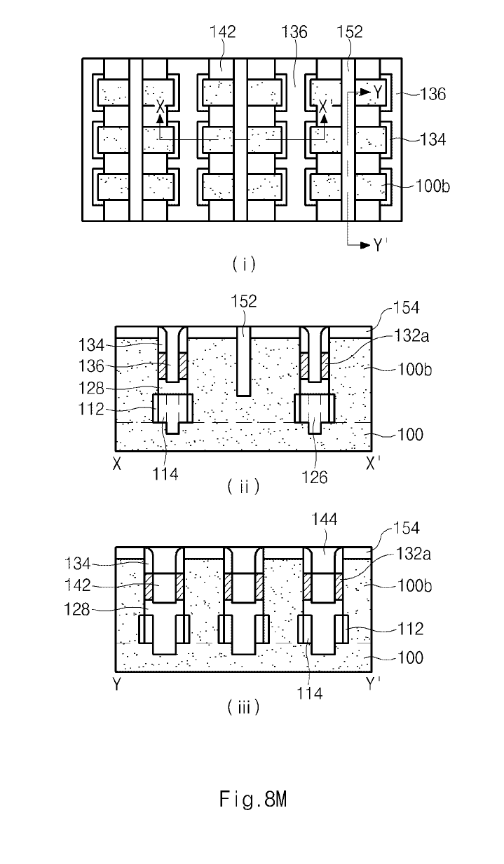

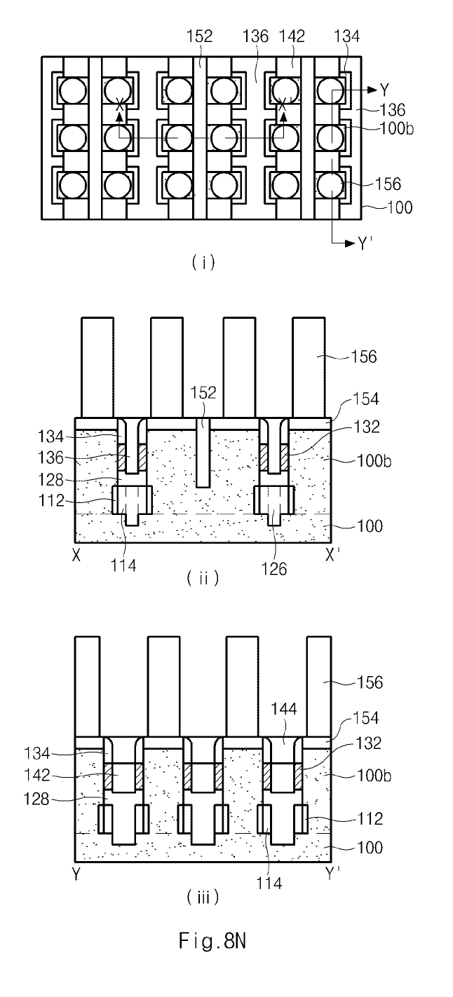

FIGS. 8A to 8P illustrate a method of manufacturing a semiconductor device according to an exemplary embodiment of the present invention, wherein (i) is a plan view, (ii) is a cross-sectional view taken along a line X-X′ of (i), and (iii) is a cross-sectional view taken along a line Y-Y′ of (i).

Referring to FIG. 8A, a mask pattern (not shown) is formed on a semiconductor substrate 100 and the semiconductor substrate 100 is etched to a predetermined thickness using the mask pattern as an etch mask to form a plurality of pillars 100b. In an embodiment, the mask pattern may have a rectangular type having the same shape as the pillar 100b. However, when it is difficult to form the pillar due to limitations of the exposure equipment, the pillar can be formed using line patterns extending in a first (X-X′) direction and line patterns extending in a second (Y-Y′) direction perpendicular to the first direction. For convenience, in FIG. 8A(ii) and (iii), the semiconductor substrate 100 and the plurality of pillars 100b protruding the semiconductor substrate 100 are illustrated separately.

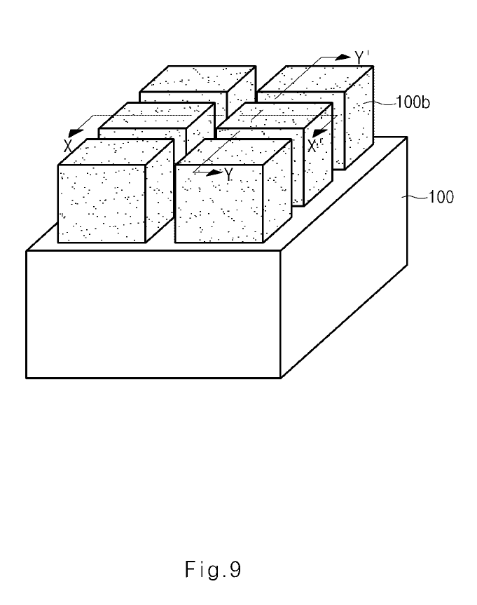

FIG. 9 is a perspective view of a semiconductor device formed by a method of manufacturing the same in an exemplary embodiment as described above. As shown in FIG. 9, the plurality of pillars 100b are formed to protrude from the semiconductor substrate 100.

Referring to FIG. 8B, a conduction layer is formed on the semiconductor substrate 100 and the pillars 100b and an etch back process for the conduction layer is performed to form a conduction layer 110 at a lower portion between the pillars 100b. Here, the conduction layer 110 may include a conduction layer for a bit line. The conduction layer 110 may include tungsten. Although not shown, before forming the conduction layer 110, a barrier metal layer may be further formed to improve adhesion between the pillar 100b and the conduction layer 110 and to form an ohmic contact. The barrier metal layer may include TiN or CoSix. Subsequently, a heat treatment process is performed to form a first junction region 112 at a sidewall of the pillar 110b. The first junction region 112 is formed by diffusing ions into the sidewall of the pillar 110b through the barrier metal layer. The first junction region 112 may be formed by combining the barrier metal layer and the pillar 100b. The first junction region may form a source or drain region. The first junction region may be formed by an ion implantation process other than the heat treatment process. However, when the first junction region is formed at a lower portion of the pillar as describe above, it is difficult to form the first junction region and thus it is preferably formed using the heat treatment process.

Referring to FIG. 8C, an insulating layer is formed on the pillars 100b and an etch back process is performed to form a first spacer 116 at a sidewall of the pillar 100b. Subsequently, the conduction layer 110 is etched to expose the semiconductor substrate 100 using the first spacer 116 as an etch mask, thereby simultaneously forming first bit line conduction layer 114 and the trench 118. Here, when forming the trench 118, the semiconductor substrate 100 may be further etched to a predetermined thickness. The first bit line conduction layer 114 may be formed to surround the pillar 100b.

Referring to FIG. 8D, a bit line separation insulating layer 120 is formed to fill the trench (118 of FIG. 8C). Here, the bit line separation insulating layer 120 electrically insulates the first bit line conduction layers 114 that are adjacent to each other. Subsequently, a mask pattern 122 extending in the first (X-X′) direction (a left and right direction of FIG. 8D) is formed to expose the pillar 100b.

Referring to FIG. 8E, the first spacer 116 and the bit line separation insulating layer 120 are etched using the mask pattern (122 of FIG. 8D). In an embodiment, as shown in FIG. 8E(i), the trench 124 may be formed to expose the semiconductor substrate 100 between adjacent pillars 100b in the first (X-X′) direction (a left and right direction of FIG. 8E).

Referring to FIG. 8F, a conductive layer is formed on the semiconductor substrate 100, the pillars 100b, and the first bit line conduction layers 114 and an etch back process is performed to form the second bit line conduction layers 126 connecting the first bit line conduction layer 114. In an embodiment, the second bit line conduction layer 126 may connect the first bit line conduction layer 114 along the first (X-X′) direction (a left and right direction of FIG. 8F). Afterward, the bit line separation insulating layer 120 may be removed to expose the semiconductor substrate 100 between adjacent pillars 100b in the second direction (Y-Y′ direction of FIG. 8F)

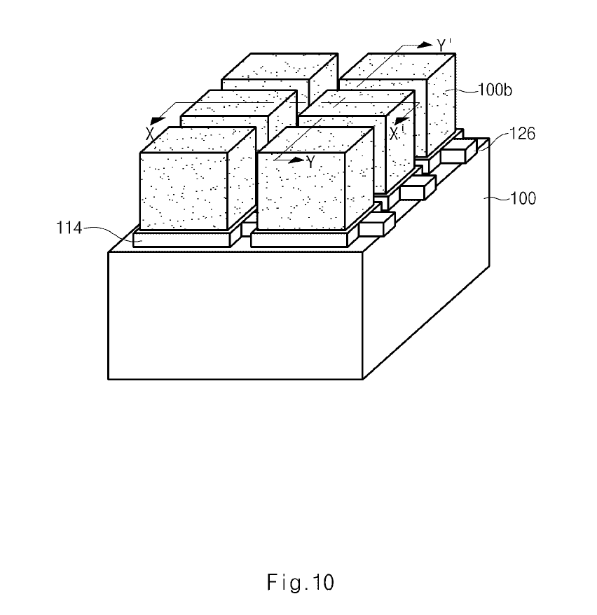

FIG. 10 illustrates a perspective view of a semiconductor device formed by a method of manufacturing the same according to an exemplary embodiment as described above. As shown in FIG. 10, the semiconductor device includes the first bit line conduction layers 114 surrounding the perimeters of the portions of the plurality of pillars 100b and the second bit line conduction layers 126 connecting the first bit line conduction layers 114 along the first direction. The first bit line conduction layer 114 and the second bit line conduction layer 126 are connected to serve as a bit line. The bit line surrounding the pillar 100b prevents the bit line resistance from increasing.

Referring to FIG. 8G, an insulating layer 128 is formed on the first bit line conduction layers 114, the second bit line conduction layers 126 and the semiconductor substrate 100 between the pillars 100b. An etch back process is performed to form an interlayer insulating layer 128 on the first bit line conduction layers 114, the second bit line conduction layers 126 and the semiconductor substrate 100 between the pillars 100b. In an embodiment, the interlayer insulating layer 128 is formed so that the plurality of pillars 100b are spaced apart, the first bit line conduction layers 114 adjacent to each other in the second direction (a Y-Y′ direction of FIG. 8G) are electrically spaced apart, and the first and second bit line conduction layers 114 and 126 are spaced apart from a gate which will be formed later.

The interlayer insulating layer 128 is formed of the same material as the first spacer (116 of FIG. 8F) and the insulating layer (120 of FIG. 8F). Since the first spacer (116 of FIG. 8F) and the insulating layer (120 of FIG. 8F) are formed of the same material as the interlayer insulating layer 128, in the above-described etch back process for the interlayer insulating layer 128, the first spacer (116 of FIG. 8F) and the insulating layer (120 of FIG. 8F) are also etched to remain on the first bit line conduction layers 114 and the semiconductor substrate 100 an thus, for convenience, it illustrates to be unified with the interlayer insulating layer 128 of FIG. 8G(ii). In an embodiment, since the interlayer insulating layer 128 is formed to electrically insulate the bit line from a gate to be formed later, it may have a predetermined thickness for electrical insulation. Subsequently, an ion implantation process 130 for adjusting a threshold voltage Vt may be performed on exposed sidewalls of the pillars 100b over the interlayer insulating layer 128 to form an ion implanted region.

Referring to FIG. 8H, a conduction layer is formed on the interlayer insulating layer 128 and an etch back for the conduction layer is performed. The etch back process for the conduction layer may be performed to expose upper portions of the sidewalls of the pillars 100b. Subsequently, an insulating layer is formed on the conduction layer and an etch back process for the insulating layer is performed to form second spacers 134. The conduction layer is etched using the second spacers 134 as an etch mask to expose the interlayer insulating layer 128, thereby forming first gate conduction layers 132. At this time, the conduction layer for the first gate conduction layer 132 serves as a gate and may include tungsten. The first gate conduction layer 132 may be formed to expose the interlayer insulating layer 128, but it is not preferably formed to overetch the interlayer insulating layer 128. Since it is possible to expose the second bit line conduction layer 126, a bridge with a conduction layer to be formed later is caused.

Referring to FIG. 8I, a gate separation insulating layer 136 is formed to insulate the first gate conduction layers 132 and then a mask pattern 138 extending in the second (Y-Y′) direction perpendicular to the first direction is formed. The mask pattern 138 may be disposed between adjacent pillars 100b in the first (X-X′) direction (a left and right direction of FIG. 8I).

Referring to FIG. 8J, the gate separation insulating layer 136 is removed using the mask pattern as an etch mask to expose the interlayer insulating layer 128, thereby forming trenches 140. Here, the trench 140 may be formed to expose the interlayer insulating layer 128 between the pillars 100b arranged along the Y-Y′ direction.

Referring to FIG. 8K, a conduction layer is formed to fill the trenches (140 of FIG. 83) and an etch back process is performed to form a second gate conduction layer 142 connecting the first gate conduction layers 132. The second gate conduction layer 142 may connect the first gate conduction layers arranged along the second (Y-Y′) direction. Subsequently, an insulating layer 144 fills the trenches 140 over the second gate conduction layers 142. The insulating layer 144 is then plaranarized to be at the same level as the pillar 100b. In FIG. 8K(III), the insulating layer 144 is formed on the second gate conduction layer 142. However, in FIG. 8K(i), the insulating layer 144 is not shown.

Instead, the second gate conduction layer 142 is shown in order to illustrate the connection between the second gate conduction layer 142 and the first gate conduction layer 132.

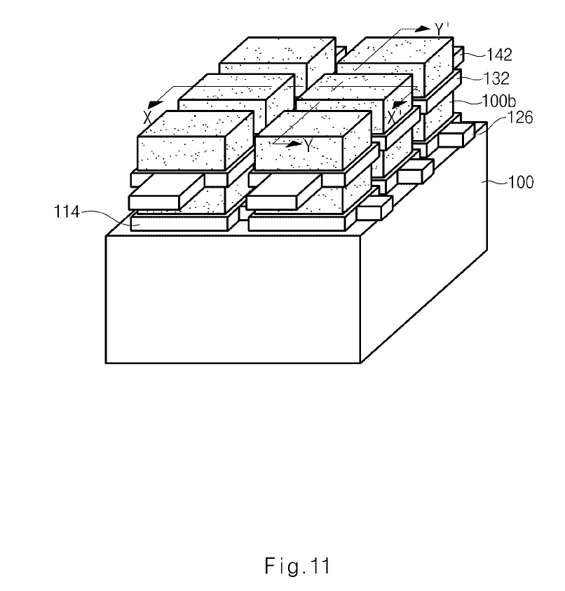

FIG. 11 illustrates a perspective view of a semiconductor device formed by a method of manufacturing the same according to an exemplary embodiment as described above. As shown in FIG. 11, the semiconductor device includes the first bit line conduction layers 114 surrounding the perimeters of the portions of the plurality of pillars 100b, the second bit line conduction layers 126 connecting the first bit line conduction layers 114 along the first direction, the first gate conduction layers 132 spaced apart from the first and second bit line conduction layers 114 and 126 by having the interlayer insulating layer 128 therebetween, and the second conduction layers 142 connecting the first gate conduction layers 132 along the second direction.

Referring to FIG. 8L, an insulating layer 146 is formed on the pillars 100b to expose portions of the pillars 100b and spacers 148 are formed at sidewalls of the insulating layer 146. Subsequently, the pillars 100b, the insulating layer 144 and the second conduction layer 142 are etched using the spacer 148 as an etch mask to form trenches 150. The spacers 148 are formed in order to form trenches 150 having a smaller width than a trench formed when the pillar 100b is etched using the insulating layer 146 as an etch mask. The trench 150 may be formed to a depth such that it divides the first and the second gate conduction layers 132 and 142 into two parts, respectively, as shown in FIG. 8L(ii). Afterward, the insulating layer 146 and the spacers 148 are removed.

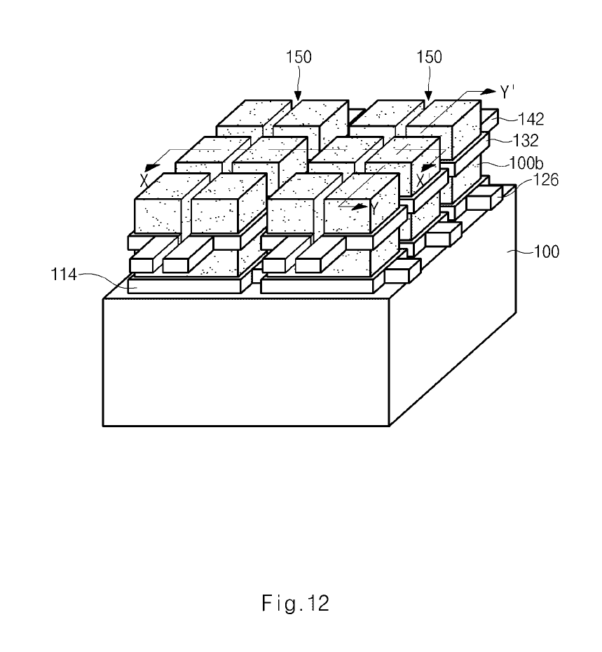

Referring to FIG. 12, the semiconductor device includes the first bit line conduction layers 114 surrounding the perimeters of the portions of the plurality of pillars 100b, the second bit line conduction layers 126 connecting the first bit line conduction layers 114 along the first direction, the first gate conduction layers 132 spaced apart from the first and second bit line conduction layers 114 and 126 by the interlayer insulating layer 128, the second conduction layers 142 connecting the first gate conduction layers 132 along the second direction, and trenches that divide the first and second gate conduction layers 132 and 142, respectively. The first and second gate conduction layers 132 and 142 are connected to serve as a gate.

Referring to FIG. 8M, an insulating layer fills the trench 150, thereby forming separation layers 152. Although not shown in FIG. 8(ii) and (iii), the separation layer 152 may divide the insulating layer 144 and the second conduction layer 142 along the second (Y-Y′) direction into two parts having the same width, respectively. Subsequently, an ion implantation process for upper portions of the pillars 100b is performed to form second junction regions 154. The second junction regions 154 may serve as a source or drain. Here, the second junction region 154 together with the first junction region 112 forms a channel in each of the pillars 100b disposed on the sidewall of the first gate conduction layer 132. Since the separation layer 152 separates the pillars 100b, storage nodes can be formed on the separated pillars. That is, one pillar is divided into a two pillar unit by the separation layer 152 and two storage units can be formed on the two divided pillar units, thereby easily obtaining high integration of the semiconductor device.

Referring to FIG. 8N, a storage unit 156 is formed on the second junction region 154. Although not shown, before forming the storage unit 156 on the second junction region 154, a storage node contact plug may be further formed. The storage unit 156 may include a capacitor.

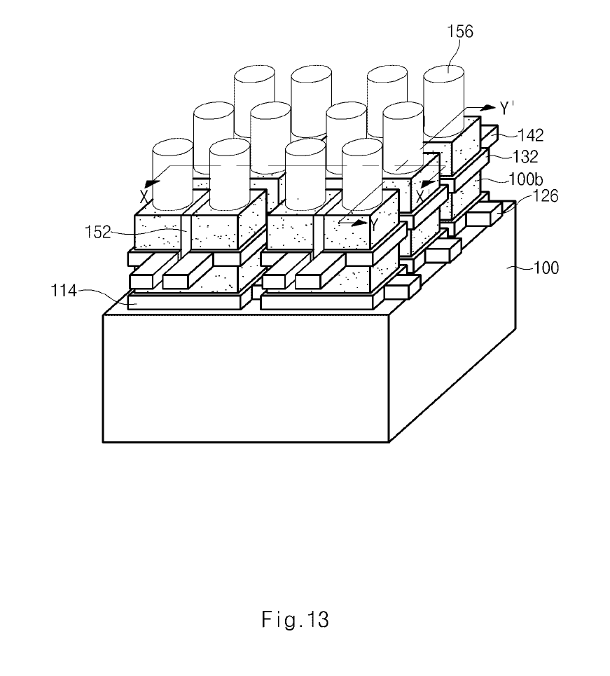

Referring to FIG. 13, the semiconductor device includes the first bit line conduction layers 114 surrounding the perimeters of the portions of the plurality of pillars 100b, the second bit line conduction layers 126 connecting the first bit line conduction layers 114 along the first direction, the first gate conduction layers 132 spaced apart from the first and second bit line conduction layers 114 and 126 by the interlayer insulating layer 128, the second conduction layers 142 connecting the first gate conduction layers 132 along the second direction, the separation layers 152 dividing the first and second gate conduction layers 132 and 142 into two parts, respectively, and the storage nodes 156 connected to the upper portion of the pillars 100b.

According to an exemplary embodiment as described above, when the bit lines, which surround lower portions of the pillars and extend in the first direction, and gates, which are electrically insulated from the bit lines and extend in the second direction perpendicular to the first direction, are formed, the separation layer is formed to separate each of the pillars, thereby forming semiconductor device capable of being highly integrated.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

An embodiment of the present invention includes the following methods:

1. A method of forming a cell array, comprising:

forming a plurality of pillars protruding from a semiconductor substrate;

forming bit lines surrounding the plurality of pillars and extending in a first direction;

forming gates spaced apart from the bit lines, the gates surrounding the plurality of the pillars over the bit lines and extending along a second direction perpendicular to the first direction; and

forming separation layers separating the gates along the second direction.

2. The method of claim 1, wherein the forming the bit lines includes:

forming first bit line conduction layers surrounding the plurality of pillars; and

forming second bit line conduction layers coupling the first bit line conduction layers in the first direction.

3. The method of claim 2, wherein the forming each of the first bit line conduction layers includes:

forming a bit line conduction layer to be formed in the pillars and etching back the bit line conduction layer;

forming first spacers at sidewalls of the bit line conduction layer and the pillars;

etching the bit line conduction layer using the first spacers as a mask; and

forming a bit line separation insulating layer to be disposed between the first spacers.

4. The method of claim 3, the method further comprising performing a heat treatment process to form a first junction region at a sidewall of each of the pillars.

5. The method of claim 2, wherein the forming each of the second bit line conduction layers includes:

removing the first spacers disposed at sidewalls of pillars adjacent in the first direction;

forming a bit line conduction layer formed between the pillars adjacent in the first direction; and

etching back the bit line conduction layer.

6. The method of claim 5, the method further comprising:

forming an insulating layer over the first bit line conduction layer and the second bit line conduction layer; and

performing an etch back process for the first spacers and the bit line separation insulating layer formed between pillars in the second direction and the insulating layer to form an interlayer insulating layer over the first bit line conduction layers, the second bit line conduction layers, and the semiconductor substrate.

7. The method of claim 1, the method further comprising:

performing an ion implantation process on exposed sidewalls of the pillars over the interlayer insulating layer to perform an ion implantation for adjusting a threshold voltage.

8. The method of claim 2, wherein the forming the gate includes:

forming gate conduction layers surrounding the pillars; and

forming second gate conduction layers coupling the first gate conduction layers in the second direction.

9. The method of claim 8, wherein the forming each of the first gate conduction layers includes:

forming a conduction layer over the interlayer insulating layer and performing an etch back process;

forming second spacers at sidewalls of the pillars and the interlayer insulating layer; and

etching the conduction layer using the second spacers as a mask.

10. The method of claim 8, wherein the forming each of the second gate conduction layers includes:

forming a gate separation insulating layer between the first gate conduction layers;

forming a mask pattern over a region between the pillars in the first direction and extending in the second direction;

etching the gate separation insulating layer to expose the interlayer insulating layer using the mask pattern as a mask, thereby forming a trench; and

forming a conduction layer in the trench and performing an etch back process.

11. The method of claim 1, wherein the forming the separation layers includes:

forming a trench to divide the gate into two divided gates in the second direction; and

forming the insulating layer to fill the trench.

12. The method of claim 11, wherein the two divided gates have substantially the same width.

13. The method of claim 1, the method further comprising performing an ion implantation process on upper portions of the pillars to form second junction regions.

14. The method of claim 13, the method further comprising forming storage units coupled to the second junction regions.

15. A method for forming a cell array, comprising:

forming a first pillar and a second pillar in a unit cell along a first direction;

forming a first bit line pattern surrounding the first pillar at a first level, and a second bit line pattern surrounding the second pillar at a second level;

forming a bit line coupling the first and the second bit line pattern to each other along the first direction;

forming a first separation layer dividing the first pillar into a third pillar and a fourth pillar along a second direction perpendicular to the first direction;

forming a second separation layer dividing the second pillar into a fifth pillar and a sixth pillar along the second direction perpendicular to the first direction;

forming first, second, third and fourth gate patterns surrounding the third, the fourth, the fifth and the sixth pillars at third, fourth, fifth and sixth levels, respectively;

forming a first gate line coupling the first gate pattern to that of a neighboring unit cell along the second direction; and

forming second, third and fourth gate lines coupling the second, the third and the fourth gate patterns to those of the neighboring unit cell with each other along the second direction, respectively.

16. The method of claim 15, the method further comprising:

forming first and second storage node patterns configured to be coupled to the first bit line pattern through the third and the fourth gate patterns; and

forming third and fourth storage node patterns configured to be coupled to the second bit line pattern through the fifth and the sixth gate patterns.

17. A semiconductor device comprising:

a cell array of claim 1;

a signal amplification coupled to the bit lines of the cell array;

a word line driving unit coupled to the gates of the cell array; and

a driving unit coupled to the signal amplification unit and the word line driving unit.

18. The semiconductor device of claim 17, the device further comprising:

a row decoder;

a column decoder; and

a semiconductor device controller.

19. A semiconductor module, comprising:

a semiconductor device of claim 17; and

an external input/output (I/O) line.

20. The semiconductor module of claim 19, wherein the semiconductor module includes one or more semiconductor devices of claim 17.

21. The semiconductor module of claim 19, the module further comprising:

a semiconductor module data link; and

a semiconductor module command link electrically coupled to the external input/output (I/O) line.

22. A semiconductor system, comprising:

a semiconductor module of claim 19; and

a system controller.

23. The semiconductor system of claim 22, wherein the semiconductor module includes one or a plurality of semiconductor modules.

24. The semiconductor system of claim 22, the system further comprising:

a system command link; and

a system data link electrically coupled to the system controller.

25. An electronic unit, comprising:

a semiconductor system of claim 22; and

a processor.

26. The electronic unit of claim 25, wherein the processor includes a central processing unit (CPU) or a graphic processing unit (GPU).

27. The electronic unit of claim 25, wherein the CPU is part of a computer or a mobile device.

28. The electronic unit of claim 25, wherein the GPU is part of a graphic device.

29. An electronic system comprising:

an electronic unit of claim 25; and

an interface.

30. The electronic system of claim 29, wherein the interface includes any of a monitor, a key board, a pointing device (mouse), universal serial bus (USB), a display, and a speaker.

What is claimed is:

1. A cell array comprising:
first and second pillars disposed to protrude from a semiconductor substrate;
bit lines surrounding the first and second pillars and extending along a first direction;
first and second gates spaced apart from the bit lines, formed over the bit lines, and extending along a second direction perpendicular to the first direction, the first gate surrounding a portion of the first pillar, the second gate surrounding a portion of the second pillar; and
a separation layer separating the first and second gates along the second direction.

2. The cell array of claim 1, the cell array further comprising first and second storage units formed over the first and second the pillars separated by the separation layer.

3. The cell array of claim 1, wherein each of the bit lines includes:
a first bit line conduction layer surrounding the first and second pillars; and
a second bit line conduction layer coupling the first bit line conduction layers along the first direction.

4. The cell array of claim 1, wherein each of the first and second gates includes:
a first gate conduction layer surrounding the first and second pillars; and
a second gate conduction layer coupling the first gate conduction layers along the second direction.

5. The cell array of claim 4, wherein the first and second gate conduction layer is divided into two parts by the separation layer, each of the two parts having substantially the same width.

6. The cell array of claim 1, the cell array further comprising a first junction region formed between the first and second pillars and the bit lines.

7. The cell array of claim 2, the cell array further comprising a second junction region formed between the first and second pillars and the storage units.

8. The cell array of claim 1, the cell array further comprising an ion implanted region configured to control a driving voltage at a sidewall of each of the first and second pillars over which the gate is disposed.

9. A cell array comprising:
a first pillar and a second pillar formed in a unit cell along a first direction;
a first bit line pattern surrounding the first pillar at a first level, and a second bit line pattern surrounding the second pillar at a second level;
a bit line coupling the first and the second bit line pattern to each other along the first direction;
a first separation layer dividing the first pillar into a third pillar and a fourth pillar along a second direction perpendicular to the first direction;
a second separation layer dividing the second pillar into a fifth pillar and a sixth pillar along the second direction perpendicular to the first direction;
first, second, third and fourth gate patterns surrounding the third, the fourth, the fifth and the sixth pillars at third, fourth, fifth and sixth levels, respectively;
a first gate line coupling the first gate pattern to that of a neighboring unit cell with each other along the second direction; and
second, third and fourth gate lines coupling the second, the third and the fourth gate patterns to those of the neighboring unit cell with each other along the second direction, respectively.

10. The cell array of claim 9, wherein the unit cell includes at least four pillar patterns, at least four gate patterns and at least two bit lines.

11. The cell array of claim 9, wherein the first and the second levels are different from the third, the fourth, the fifth and the sixth levels.

12. The cell array of claim 9, wherein the first and the second levels are at substantially the same level, and the third, the fourth, the fifth and the sixth levels are at substantially the same level.

13. The cell array of claim 9, wherein the first, second, third and fourth gate patterns are configured to be insulated from the first and the second bit line patterns.

14. The cell array of claim 9, wherein the first, second, third and fourth gate patterns are formed at a level higher than the first and the second bit line patterns, respectively.

15. The cell array of claim 9, the cell array further comprising:
first and second storage node patterns configured to be coupled to the first bit line pattern through the third and the fourth gate patterns; and
third and fourth storage node patterns configured to be coupled to the second bit line pattern through the fifth and the sixth gate patterns.
